(19) United States
(12) Patent Application Publication
(10) Pub. No.: US 2025/0199299 A1
(43) Pub. Date: Jun. 19, 2025

(54) EXTENDED DEPTH OF FIELD LIGHT SHEET GENERATING ASSEMBLY

(71) Applicant: OSELA INC., Lachine (CA)

(72) Inventors: Francis CAYER, Lachine (CA); Alexandre GERMAIN, Lachine (CA)

(73) Assignee: OSELA INC., Lachine (CA)

(21) Appl. No.: 18/974,088

(22) Filed: Dec. 9, 2024

Related U.S. Application Data
(60) Provisional application No. 63/610,618, filed on Dec. 15, 2023.

(51) Int. Cl. G02B 27/00; H01S 5/026

(52) U.S. Cl. CPC G02B 27/0075; H01S 5/026

(57) ABSTRACT

A light sheet generating assembly is provided, for generating a light sheet having an extended depth of field (EDOF) over an EDOF range from a light beam. The light beam has a propagation axis and a light intensity distribution transverse to the propagation axis. The light sheet generating assembly includes a depth of field extender configured to alter an electrical field of the light beam to redistribute the light intensity of the light beam along a first transverse axis orthogonal to the propagation axis according to (1) an inner intensity peak, and (2) outer intensity features having an intensity below an outer intensity threshold over said EDOF range. The light sheet generating assembly further includes a line generator configured to redistribute the light intensity of the light beam along a second transverse axis orthogonal to the first transverse axis and to the propagation axis into a line.

This application claims the benefit of U.S. Provisional Applications No. 63/610,618, filed Dec. 15, 2023, herein incorporated by reference in its entirety for all purposes

### TECHNICAL FIELD

The technical field generally relates to improving the depth of field of a laser beam and more particularly concern the case of the generation of a laser light sheet having extended depth of field properties on its thickness axis.

### BACKGROUND

Light sheets are typically used for a variety of applications where an object is to be illuminated by a laser line. Such applications for example include industrial machine vision systems projectors, visual alignment applications and visual art applications.

It is known in the art to generate light sheets by transforming a Gaussian or Gaussian-like light beam. Different characteristics of the initial light beam can affect the properties of the resulting light sheet. The Depth of field (DOF) relates to the variation of the properties of a laser beam upon its propagation along a propagating axis, typically denoted the “z” axis by convention. It is known in the art that a typical Gaussian laser beam, TEM00 mode, has a depth of field twice the Rayleigh range or length (ZR). The 2D radial profile and the Gaussian intensity profile of a Gaussian light beam are shown in FIGS. 1A and 1B (PRIOR ART), while the relevant parameters of such a Gaussian beam are illustrated on FIG. 1C (PRIOR ART). The Rayleigh range ZR corresponds to the distance along the propagation axis at which the thickness of the laser beam w(z) has increased by a factor \sqrt{2} relative to its waist w₀, the smallest thickness along propagation axis. The smaller the waist, the shorter Z_{R}, since the diffraction properties of a Gaussian beam imply that beams with smaller waists are more divergent. This is for example illustrated in FIG. 2 (PRIOR ART), where w1<w2<w3. The word “thickness” as used herein is understood to relate to the transverse dimension of a laser beam or line. As will be readily understood by one skilled art, for a round beam, the diameter and thickness of the beam are equivalent.

As the beam thickness increases, its peak intensity falls. The consequences are a decrease of the resolution in x and/or y (the axes perpendicular to the propagation direction) and a lower light density.

In machine vision systems, increasing the beam thickness at the object plane leads to a blurrier image at the image plane (sensor). The resolution of the image becomes poor and or the camera does not have enough power density to measure something. This happens when, for example, a scanner cannot be kept at a fixed distance from the object. A typical example would be a fixed scanner scanning from above different heights of boxes on a conveyor or a hand scanner used by an operator constantly moving relative to the scanned object.

A few solutions exist to try and overcome this problem. Diffractive optic elements (DOEs) such as multi-level diffraction gratings or metalenses can be manufactured to provide a laser spot having the diffracted-limited spot size of a gaussian beam over long propagation distances (Diffractive Limit Continuous Multi Foci Lenses). Also known in the art are discrete multi foci lens, where the lens is partially focused at different z distances. Tunable lenses have surfaces that are altered in time to vary their focus. Truncating a Gaussian-beam or increasing its waist dimension are other options. Axicons, either refractive or diffractive, and metalenses can alternatively be used to generate Bessel like beam. These are known in the art as “self-healing” or non-diffracting beams, as their central lobe does not diffract and does not diverge with propagation. Bessel-like beams however have sidelobes which can be detrimental to their use for machine vision systems. Bessel beam can also be used to generate a lattice light sheet.

While these solutions work, they all have drawbacks. Truncating a beam can lead to poor performance. Tunable lenses are mechanically complex and require electronic components. Lattice light sheets are complex systems that require opto-mechanical devices and multiple optic components. Prior art approaches also inherently create beams having a radial symmetry. Their extended depth of field property is loss when transformed into a laser line. They can be scanned using various oscillator devices, but these are non-static complex system having opto-mechanical, electronic, and optic components. Moreover, the camera acquisition window must be synchronized with the oscillator movements.

There remains a need in the art for means to generate a light sheet having an extended depth of field that alleviates at least some of the drawbacks of the prior art.

### SUMMARY

In accordance with one aspect, there is provided a light sheet generating assembly for generating a light sheet having an extended depth of field (EDOF) over an EDOF range from a light beam, the light beam having a propagation axis and a light intensity distribution transverse to the propagation axis, the light sheet generating assembly comprising:
a depth of field extender configured to alter an electrical field of the light beam to redistribute the light intensity of the light beam along a first transverse axis orthogonal to the propagation axis according to:
   an inner intensity peak; and
   outer intensity features having an intensity below an outer intensity threshold over said EDOF range; and
a line generator configured to redistribute the light intensity of the light beam along a second transverse axis orthogonal to the first transverse axis and to the propagation axis into a line.

In some implementations, the depth of field extender comprises a phase-altering component configured to alter a phase of the electrical field of the light beam and/or an intensity-altering component configured to alter an amplitude of the electrical field of the light beam.

In some implementations, the depth of field extender comprises an optical surface having a unidimensional surface profile along the first transversal axis providing said redistribution of the light intensity of the light beam along the first transverse axis. In some variants, the unidimensional surface profile is acylindrical. On some variants, the unidimensional surface profile has no inflexion points.

In some implementations, the inner intensity peak has a constant width over the EDOF range.

In some implementations, the inner intensity peak has a width over the EDOF range which is scaled to a secondary parameter. The secondary parameter may be a point spread function dimension of a camera receiving the light sheet thereon.

In some implementations, wherein the outer intensity threshold is between about 30% and about 50% of a maximum intensity of the inner intensity peak.

In some implementations, the line generator comprises a refractive optical element.

In some implementations, the line generator comprises a diffractive optical element.

In some implementations, the line generator is a low-speckle laser line generator comprising:
a beam divider configured to divide the light beam into incoherent multiple sub-beams propagating in a same propagation plane; and
a sub-beam converter generating a plurality of laser light sheets, each laser light sheet being associated with a corresponding one of the sub-beams, each laser light sheet extending within the propagation plane, the laser light sheets intersecting a projection plane to define laser line elements overlapping at least partially to form said low-speckle laser line, the laser line elements having respective speckle patterns which are at least partially uncorrelated.

In some implementations, the line generator is configured to redistribute the light intensity of the light beam along the second transverse axis according to a flat uniform profile, a super gaussian profile or a cosine correction profile.

In some implementations, the line generator is positioned after the depth of field extender.

In some implementations, the line generator is positioned ahead of the depth of field extender.

In some implementations, the depth of field extender and the line generator form opposite surfaces of a monolithic optical component.

In some implementations, there is provided a light sheet generating assembly according to any variant above, in combination with a laser light source generating the light beam. The laser light source may comprise a laser diode.

Other features and advantages will be better understood upon of reading of detailed embodiments with reference to the appended drawings.

### BRIEF DESCRIPTION OF THE DRAWINGS

FIGS. 1A to 1C (PRIOR ART) illustrates the spatial parameters of a Gaussian light beam.

FIG. 2 (PRIOR ART) shows the evolution of the thickness of Gaussian light beams upon propagation.

FIG. 3 schematically illustrates a light sheet generating assembly according to one embodiment.

FIG. 4 is an elevated side view of a light sheet generating assembly;

FIG. 4A is a side view in the XZ plane of the light sheet generating assembly of FIG. 4; FIG. 4B is a side view in the YZ plane of the light sheet generating assembly of FIG. 4.

FIG. 5 is a graph comparing dimensions as a function of distance of light sheets generated from a Gaussian light beam and from a light sheet generating assembly according to one implementation; FIGS. 5A and 5B show the evolution of the corresponding light intensity profiles.

FIGS. 6A to 6C show different examples of intensity profiles of light sheets with respect to an outer intensity threshold.

FIG. 7 shows the evolution of the FWHM thickness of a light sheet generated by a light sheet generating assembly as described herein as a function of distance. FIGS. 7A to 7C are examples of the corresponding light intensity profile at different distance points.

FIG. 8A is a representation of the unidimensional surface profile of a depth of field extender according to one embodiment; FIG. 8B illustrates the impact of a depth of field extender having such a unidimensional surface profile on the wavefront of the light beam.

FIG. 9 shows the alignment of the apex cross point of the depth of field extender and line generator centered with the input light beam.

FIGS. 10A to 10C illustrate the light sheet acting, upon propagation in the Z direction, as a telecentric (FIG. 10A), a hypercentric (FIG. 10B) or entocentric (FIG. 10C) laser line in the Y axis.

FIG. 11A illustrates the propagation of light rays r1, r2, and r3 of a light sheet over different optical path lengths to a projection plane. FIG. 11B shows the light intensity profile at points A, B and C of the projection plane.

FIG. 12 is a schematic representation of a light sheet generating assembly wherein the line generator s a low-speckle laser line generator.

FIGS. 13 to 15 show different configurations of light sheet generating assemblies using refractive complements.

FIGS. 16 to 18 show different configurations of light sheet generating assemblies using diffractive complements.

FIGS. 19A and 19B illustrate a variant where the depth of field extender includes an intensity-altering component 70 followed by a phase-altering component 72.

### DETAILED DESCRIPTION

In the following description, similar features in the drawings have been given similar reference numerals. In order not to unduly encumber the figures, some elements may not be indicated on some figures if they were already mentioned in preceding figures. It should also be understood herein that the elements of the drawings are not necessarily drawn to scale and that the emphasis is instead being placed upon clearly illustrating the elements and structures of the present embodiments.

The terms “a”, “an” and “one” are defined herein to mean “at least one”, that is, these terms do not exclude a plural number of items, unless stated otherwise. Terms such as “substantially”, “generally” and “about”, that modify a value, condition or characteristic of a feature of an exemplary embodiment, should be understood to mean that the value, condition or characteristic is defined within tolerances that are acceptable for the proper operation of this exemplary embodiment for its intended application.

Unless stated otherwise, the terms “connected” and “coupled”, and derivatives and variants thereof, refer herein to any structural or functional connection or coupling, either direct or indirect, between two or more elements. For example, the connection or coupling between the elements may be mechanical, optical, electrical, logical, or any combination thereof.

In the present description, the terms “light” and “optical”, and variants and derivatives thereof, are used to refer to radiation in any appropriate region of the electromagnetic spectrum. The terms “light” and “optical” are therefore not limited to visible light, but can also include, without being limited to, the infrared or ultraviolet regions of the electromagnetic spectrum. Also, the skilled person will appreciate that the definition of the ultraviolet, visible and infrared ranges in terms of spectral ranges, as well as the dividing lines between them, may vary depending on the technical field or the definitions under consideration, and are not meant to limit the scope of applications of the present techniques. To provide a more concise description, some of the quantitative expressions given herein may be qualified with the term “about”. It is understood that whether the term “about” is used explicitly or not, every quantity given herein is meant to refer to an actual given value, and it is also meant to refer to the approximation to such given value that would reasonably be inferred based on the ordinary skill in the art, including approximations due to the experimental and/or measurement conditions for such given value.

In the present description, the term “about” means within an acceptable error range for the particular value as determined by one of ordinary skill in the art, which will depend in part on how the value is measured or determined, i.e. the limitations of the measurement system. It is commonly accepted that a 10% precision measure is acceptable and encompasses the term “about”.

In the present description, when a broad range of numerical values is provided, any possible narrower range within the boundaries of the broader range is also contemplated. For example, if a broad range value of from 0 to 1000 is provided, any narrower range between 0 and 1000 is also contemplated. If a broad range value of from 0 to 1 is mentioned, any narrower range between 0 and 1, i.e. with decimal value, is also contemplated.

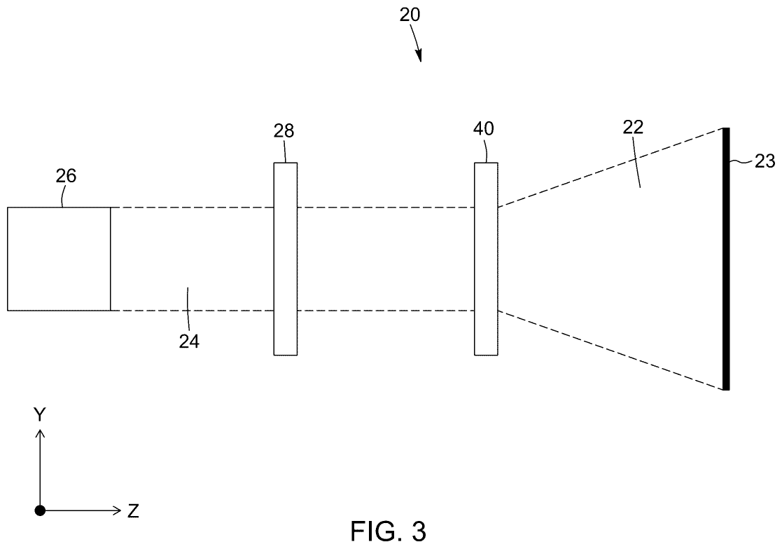

Referring to FIG. 3, in accordance with some aspects, there is provided a light sheet generating assembly 20 for generating a light sheet 22 having an extended depth of field (EDOF) over an EDOF range. As explained further below, the light sheet generating assembly 20 includes a depth of field extender 28 and a line generator 40 jointly acting to transform a light beam 24 into the light sheet 22. In some embodiments, the depth of field extender 28 and the line generator 40 provide a combination of two uniaxial and independent electrical field alterations on the light beam 24, for example a collimated TEM00 laser beam. Each alteration is effective on an axis orthogonal to the other, and both of the alteration axes are lying in a plane for which the normal vector is the propagation direction (Z).

A light sheet may be understood as a one-dimensional or quasi one-dimensional distribution of light rays. By convention, the light sheet 22 may be defined within a cartesian coordinate system XYZ as a collection of light rays propagating within a propagation plane YZ and having a very small thickness along the axis X transverse to the propagation plane YZ. Typically, the light rays fan out in the Y direction as they propagate in the Z direction. When the light sheet 22 intersects a projection plane XY, it forms a line along the Y direction, generally referred to as a laser line 23. In some implementations, light sheet generating assemblies such as described herein may be used for a variety of applications where an object is to be illuminated by a laser line. Such applications for example include industrial machine vision systems projectors, visual alignment applications and visual art applications. Laser lines typically have a finite length and a small thickness within the projection plane. For example, in some typical implementations the laser line may have a length between about 50 mm and about 300 mm. It will however be readily understood that in other implementations the laser line may be as short as about 0.1 mm or shorter, or as long as about 5000 mm or longer, without departing from the scope of protection. In addition, in some typical implementations the laser line may for example have a thickness between about 50 μm and about 500 μm. It will however be readily understood that in other implementations the laser line may be as thin as about 5 μm or thinner, or as thick as about 5000 μm or thicker, without departing from the scope of protection. In some implementations, the light sheet generating assembly described herein may be coupled with other optics such a binary grating to create a multi line pattern, which one could call an Extended Depth of Field Multi Line Projector.

The light sheet generating assembly 20 generates the light sheet 22 from a light beam 24, which may be referred to herein as an input light beam. In some implementations, the light beam 24 is generated by a laser light source 26. It will be readily understood that in some embodiments the laser light source 26 may be integrated into the light sheet generating assembly 20 as a single system, whereas in other embodiments the laser light source 26 may be separate from the light sheet assembly 20.

The laser light source 26 may be based on any type of gain medium such as for example a gas laser, a solid-state laser, a fiber laser, a dye laser or a semiconductor (diode) laser. In some implementations, the laser source is embodied by a laser diode, such as for example a Fabry-Perot (FP) laser diode, a Distributed Feedback (DFB laser diode), a Distributed Bragg Reflector (DBR) laser diode, a Quantum Cascade (QCL) laser diode, Vertical Cavity Surface Emitting Lasers (VCSELs) laser diode, or the like. In some variants, the laser diode may be a spatial multimode laser diode. In other variants, the laser diode may be a singlemode laser diode.

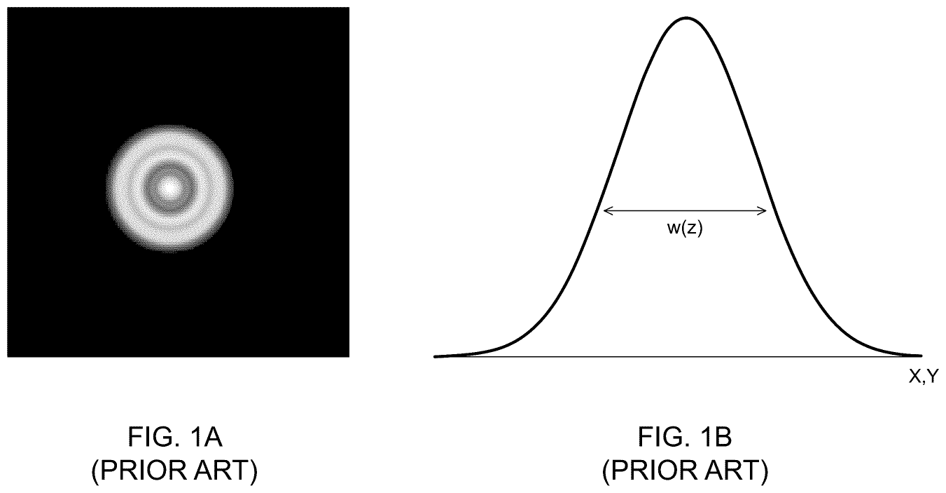

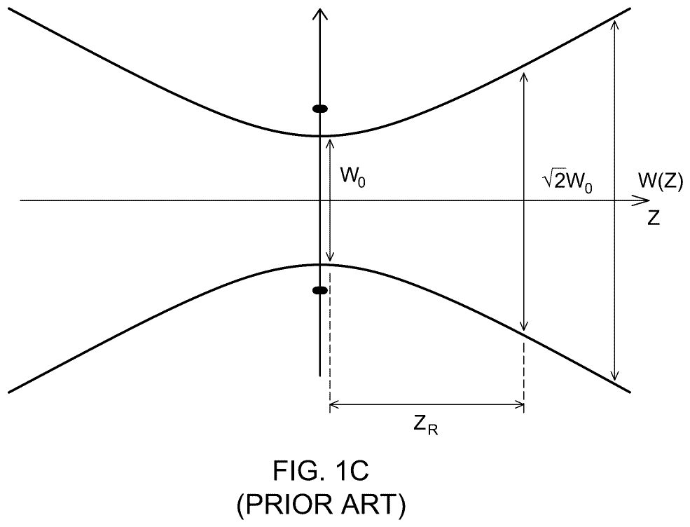

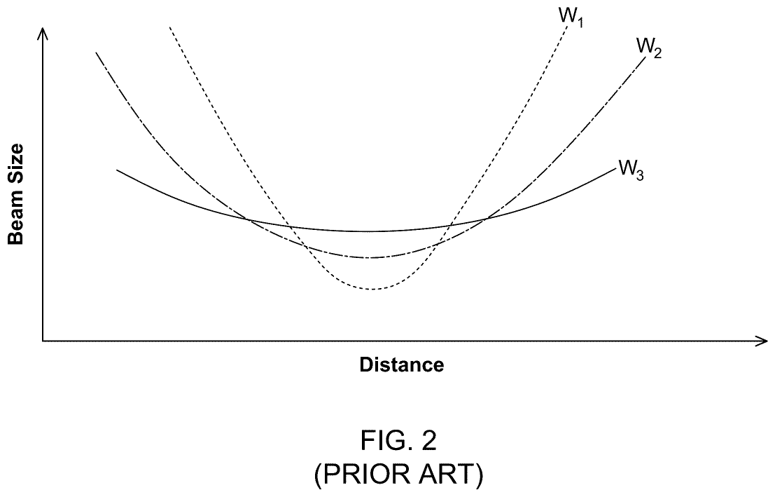

The input light beam 24 has a propagation axis (corresponding to the Z axis in the referential system of FIG. 3) and a light intensity distributed transversally to the propagation axis Z according to an input radial intensity profile. In some implementations, the input intensity profile is a Gaussian profile in both the X and Y axes, as shown in FIGS. 1A and 1B. Although the examples below use the Gaussian profile of a typical TEM00 laser beam as the input intensity profile of the light beam 24, it will be readily understood the light sheet generating assembly 20 described herein may be configured for use with a light beam having a different input profile without departing from the scope of protection. By way of example, the input intensity profile of the light beam may be a top hat profile, a truncated profile, or the like.

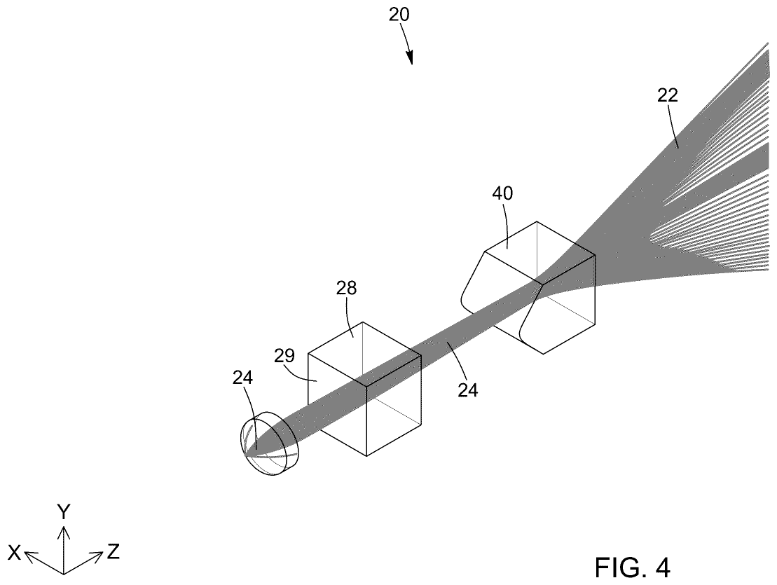

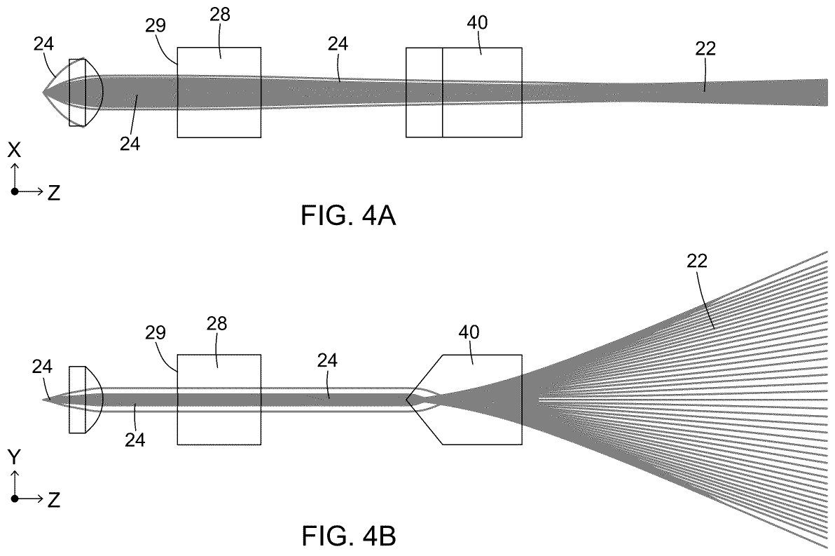

In some embodiments, the laser light source 26 may include or be combined with beam shaping and/or conditioning optics such as lenses, mirrors, filters, gratings or the like, modifying the optical properties of the input light beam prior to its transformation into a light sheet. By way of example, a collimating lens 30 may be used so that the input light beam 24 is collimated (see FIGS. 4, 4A and 4B).

Still referring to FIG. 3 and with additional reference to FIGS. 4, 4A and 4B, the light sheet generating assembly 20 includes a depth of field extender 28, as mentioned above. In some implementations, the depth of field extender 28 may be embodied by a refractive optical element, typically made of glass, or a diffractive optical element, such as for example a grating, metalens, fresnel shaped lens, etc. The depth of field extender 28 may also be embodied by a plurality of optical components collectively having the desired optical effect. In some implementations, the depth of field extender 28 may have one or more an optical surface 29. In some implementations, the optical surface 29 may be understood as an interface between two media, such as between the glass or other material of the depth of field extender 28 and the surrounding air, which is used to reflect or refract light. According to one aspect, the optical surface 29 has a unidimensional surface profile extending along a first transverse axis X orthogonal to the propagation axis Z. By convention, the first transverse axis coincides with the X axis in the accompanying figures, although one skilled in the art will readily understand that this convention is used for ease of reference only and is not meant to impart any preferential orientation to the light sheet generating assembly 20. In some implementations, the unidimensional surface profile of the optical surface 20 is configured to alter the electric field of the light beam 24 to redistribute the light intensity of the light beam 24 along the first transverse axis X according to an inner intensity peak of constant width over the EDOF range and outer intensity features having an intensity below an outer intensity threshold over the EDOF range. In one variant, the optical surface 29 alters the phase of the electric field to obtain the desired redistribution of light intensity. In other variants, the optical surface may alter the amplitude of the electric field. In some instances, the optical surface 29 may be configured to alter both the phase and amplitude of the electric field to redistribute the light intensity of the light beam 24.

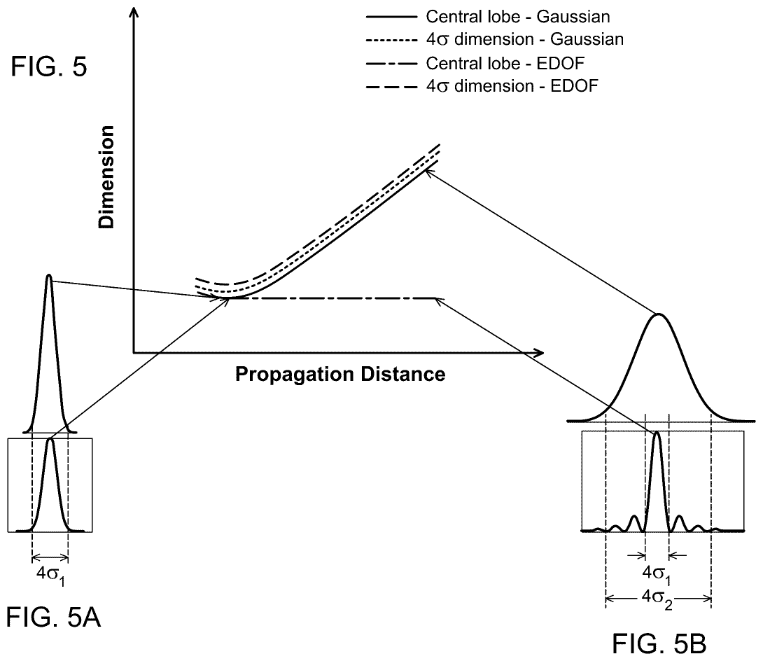

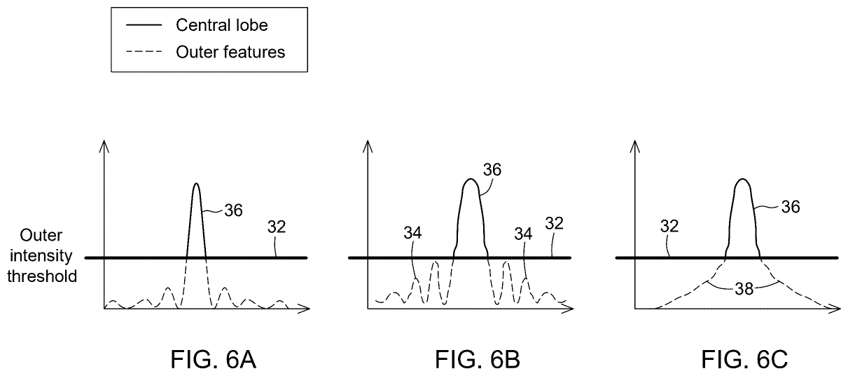

The overall effect of the depth of field extender may be understood with reference to FIGS. 5, 5A and 5B. As know in the art, typical Gaussian light beams have a Gaussian intensity profile at least over a 40 thickness, defined as 2 standard variations on either side of the peak value of the intensity profile. The 40 thickness contains about 95% of total power of the light beam. The thickness of the light beam increases with propagation because of the beam divergence, as explained above. In some implementations, the depth of field extender 28 is constructed such that the 4σ thickness follows the same diverging process, but by keeping a central lobe of a constant dimension and sending energy into the outer intensity features, described herein by all the energy contained below the outer intensity threshold 32 (see FIG. 6A). In some implementations, the outer intensity features may include sidelobes 34 on each side of the central lobe defining the inner intensity peak 36 (see FIG. 6B) and/or an extended beam “tails” 38 of the inner intensity peak 36 which has an intensity below the outer intensity threshold 32 (FIG. 6C).

The outer intensity threshold depends on the application for which the light sheet is intended. As the light beam altered by the depth of field extender continues its propagation, the width of the inner intensity peak may remain constant over the EDOF range, or scaled to a secondary parameter, such as for example following the increase of the camera point spread function dimension, all along the depth of field. The sidelobes and tails may evolve over propagation, as long as they are kept under the outer intensity threshold along the EDOF range. The EDOF range is at least a factor one times, and typically more than 3 times, the Rayleigh Range of an equivalent dimension Gaussian beam. In some implementations, the width of the inner peak of the light beam is advantageously constant all along the EDOF range, while a Gaussian profile diverges to a dimension v2 times its waist at the Rayleigh Range (Zr) point.

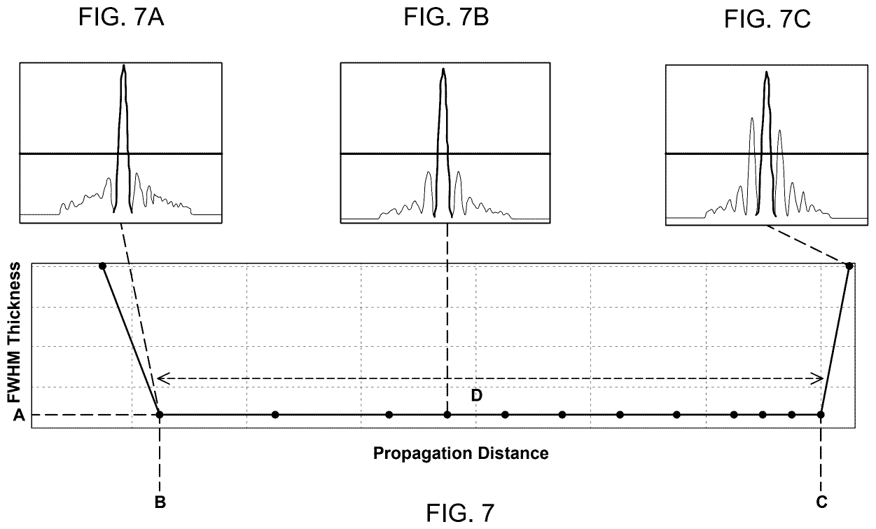

With additional reference to FIGS. 7, 7A, 7B and 7C, the structure and effect of the depth of field extender 28 may be better understood from an analysis of the wavefront properties of the light beam. The depth of field extender 28 takes the wavefront of the input light beam 24, which is for example planar and collimated, and transforms it into a wavefront which will optimize the beam intensity profile across the X axis along the EDOF range of length D, between point B marking the beginning of the EDOF range, and point C marking the end of EDOF range, such that:
The FWHM (Full Width at Half Maximum) of the inner intensity peak is constant at a value of A across the EDOF range. In other variants, the FWHM of the inner intensity peak may be scaled with propagation along the Z axis following a secondary parameter such as the point spread function dimension of the camera at position Z; and
The sidelobes and tail are kept under an outer intensity threshold 32 relative the to the inner intensity peak 36 all along the EDOF range.

In the illustrated example, FIG. 7A sows that at point B, the central lobe forming the inner intensity peak 36 emerges (in bold). The outer features 34 (not in bold) are below the intensity threshold 32 (set to 40% of the maximum intensity in the illustrated, by way of example only). In between B & C, as shown in FIG. 7B, the intensity of the outer features 34 increases slowly until reaching the threshold 32 at point C. Further than point C is out of the EDOF range (see FIG. 7C), where the intensity of at least some of the outer features 34 is now above the threshold 32.

The outer intensity threshold 32 is preferably determined by the application and may have a value from 0 to 99% of a maximum intensity of the inner intensity peak. The higher the outer intensity threshold, the longer is the EDOF range.

For example, in machine vision, the higher the number of surfaces of a sample having different reflection or scattering coefficients, the lower the outer intensity threshold should be. In semiconductor inspection, a reflective surface may be close to a scattering surface. Sidelobes hitting the reflective surface may be mistaken as the central peak at they could appear more intense than the central peak itself. A maximum threshold of about 2 to about 5% may be selected to prevent sidelobes appearing as the central peak. For inspection of parts with generally uniform surfaces, an outer intensity threshold of about 40 to about 50% may be tolerable.

In 3D printing applications, the outer intensity threshold may be of the order of about 10 to about 20%, so that the intensity of sidelobes remains below the activation threshold of the printed material.

The resulting wavefront is a free form curve that may be optimized on a case-by-case basis and expressed as:

$$φ = {e}^{ikn {Δ}_{0}} exp ( ik ( {n}_{0} - n ) d ) , \qquad ( 1 )$$

where σ is the local wavefront perturbation at coordinate x, n₀ is the refractive index of the surrounding medium, n is the refractive index of the material of the depth of field extender, Δ₀ is the apex-to-base thickness of the depth of field extender and k is the wavenumber.

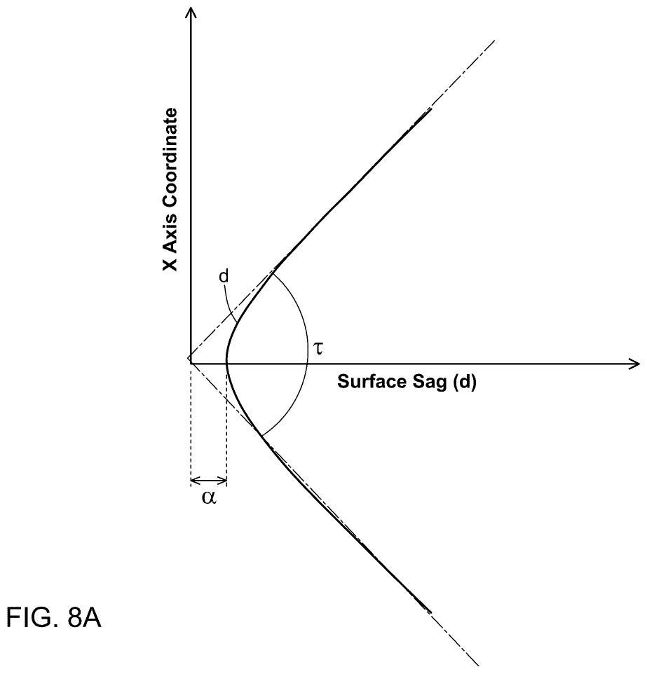

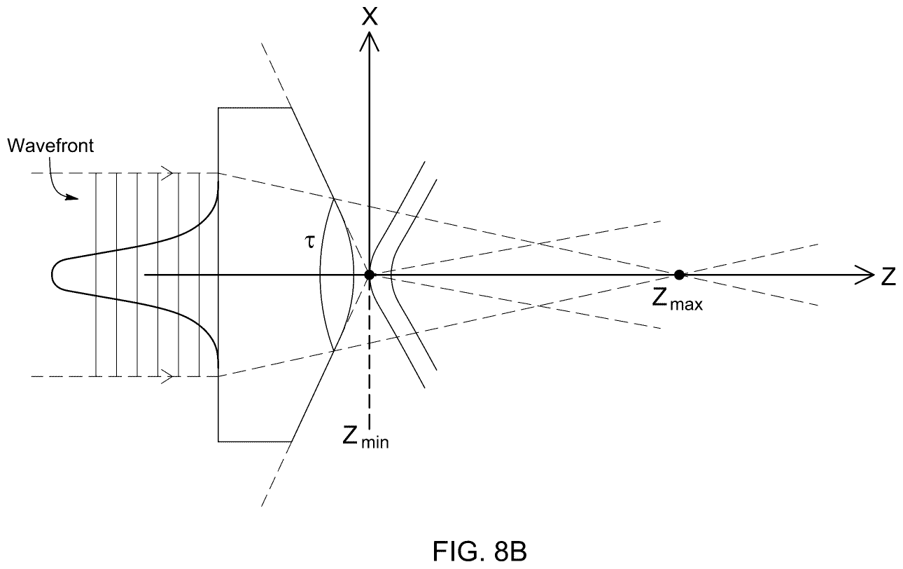

Variable d represents the unidimensional surface profile of the optical surface of the depth of field extender 28. In some embodiments, it may be represented by an acylindric equation, or the sum of a conical equation (based on a base radius of curvature and a conic constant) and polynomial coefficients up to degree 10. By way of example, in a refractive setup and for simplifications, it can be approximated by a hyperbola of the form below:

$$d = \sqrt{{α}^{2} + \frac{{x}^{2}}{{tan}^{2} \frac{τ}{2}}} \qquad ( 2 )$$

where α is a hyperbolic parameter defining the apex rounding and t is the inner angle at the hyperbolic asymptotes. The resulting unidimensional surface profile is illustrated in FIG. 8A. In this example, the unidimensional surface profile is symmetrical relative to its center (x=0), it has no inflexion points, and its derivative is continuous. FIG. 8B illustrates the impact of a depth of field extender having such a unidimensional surface profile on the wavefront of the light beam.

Referring back to FIGS. 3, 4, 4A and 4B, and as mentioned above, the light sheet generating assembly 20 further includes a line generator 40. The line generator 40 is configured to redistribute the light intensity of the light beam 24 along a second transverse axis Y, orthogonal to the first transverse axis X and to the propagation axis Z, into a uniform line. In the cartesian coordinate system used in the accompanying figures the second transverse axis coincides with the Y axis. In some implementations, the line generator 40 redistribute the intensity into a flat uniform laser line at the image plane, before and beyond. The laser line may have a flat, uniform intensity profile, a super gaussian profile, a cosine correction profile, or any other suitable intensity profile along the second transverse axis. In some implementations, the line generator 40 is designed to fan out the light beam 24 in the second transverse direction Y.

The line generator 40 may be embodied or include a refractive optical element, typically made of glass, or a diffractive optical element such as for example a grating, metalens, fresnel shaped lens, etc. In other variants, the line generator 40 may be a lenslet array, a 1D diffuser or any other line generating devices, such as the low-speckle laser line generator according to any variant disclosed in PCT/CA2023/050825, the entire contents of which is incorporated herein by reference. In some embodiments, the line generator 40 may be embodied by an acylindrical lens having a suitable optical design to generate a uniform or pseudo-uniform line. By way of example, a linear deiverging lens may be used, such as shown in U.S. Pat. No. 4,826,299 (POWELL), the entire contents of which is incorporated herein be reference. Such a lens is sometimes referred to in the art and in the present description as a “Powell lens”. In some implementations, a Powell lens may be defined by two optical surfaces, one of which is a linear conic having a short radius and a relatively large conic constant along the Y axis. The conic surface is two dimensional in the YZ plane and may be described by the following equation:

$$z = \frac{{cy}^{2}}{1 + {( 1 - ( 1 + Q ) {c}^{2} {y}^{2} )}^{1 / 2}} \qquad ( 3 )$$

where c is the curvature and Q the conic constant.

Referring to FIGS. 4, 4A and 4B, an example of a configuration of the light sheet generating assembly 20 is shown.

In the illustrated example, a laser diode diverging beam 24 having a Gaussian profile in both the X and Y axes is collimated by an aspheric molded lens 30. The light beam 24 then passes trough the depth of field extender 28, here a refractive lens made of glass, most commonly SF6, BK7 or UV FS glass. One of the input and output faces of the depth of field extender refractive lens 28 is flat. The other one of the input/output faces is flat in the Y axis and has an acylindric profile in the X axis described by equation (2). It is followed by a Powell lens 40 acting along the Y axis, embodying the line generator. The optical elements embodying the depth of field extender 20 and line generator 40 are aligned such that their apex cross point is centered with the input light beam 24 (see FIG. 9). Between the depth of field extender 28 and the line generator 40, the light beam 24 remains collimated along the Y axis, and has the wavefront properties induced by the depth of field extender 28 along the X axis. After the line generator 40, the beam defines the light sheet 22, that is, it acts as diverging laser line. Optical optics may be added to make the line hypercentric or telecentric.

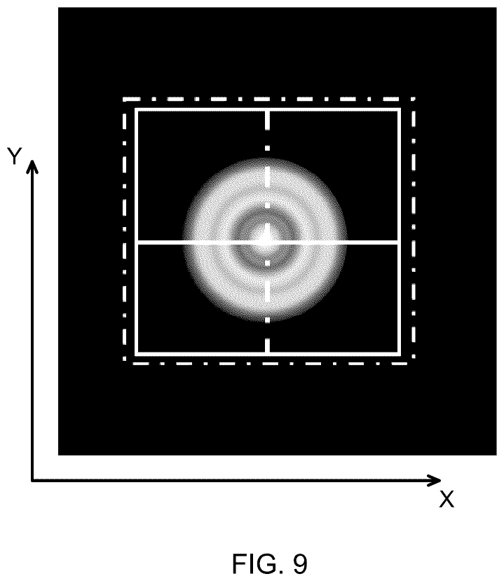

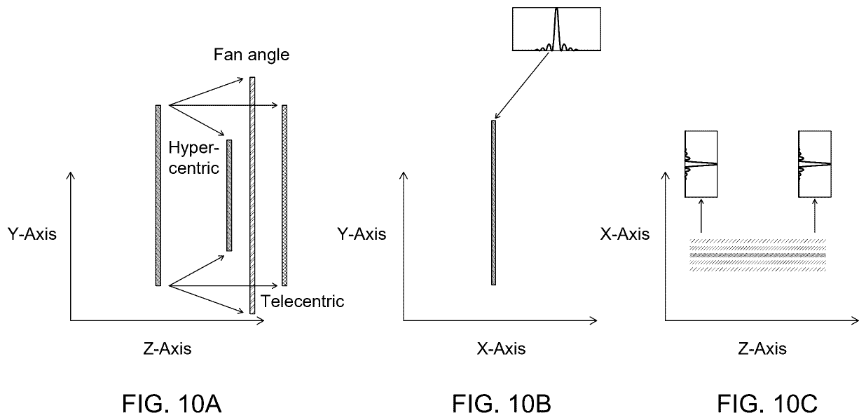

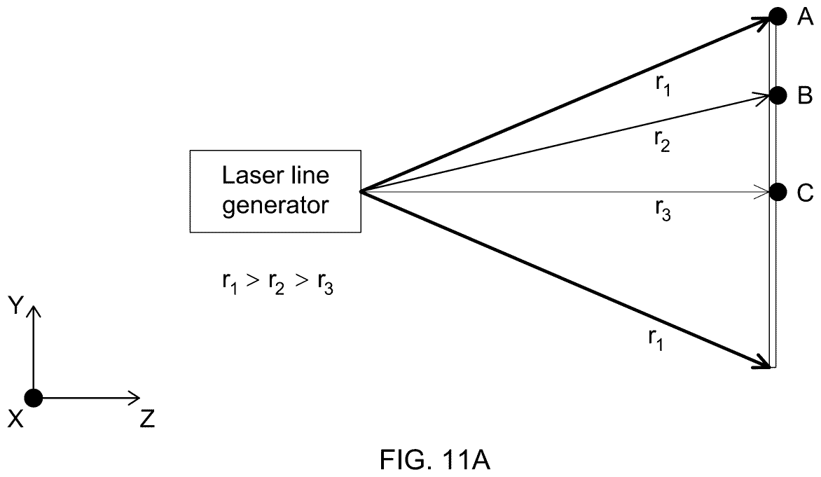

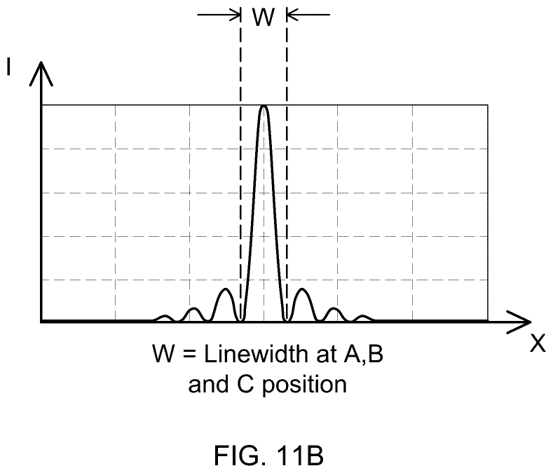

As one skilled in the art will understand, the output of a light sheet generating assembly according to embodiments described herein may be understood as a static uniaxial quasi bessel light sheet. The light sheet acts, upon propagation in the Z direction, either as a telecentric, hypercentric or entocentric laser line in the Y axis. It also has an extended depth of field non-diffracted profile on its thickness axis (X Axis). This is illustrated in FIGS. 10A to 10C. More simplified, the laser line central thickness, when measured above sidelobes threshold, is kept constant within propagation for a certain amount of distance. In some variants, the light sheet generating assembly provides a uniform inner peak size along the laser line on all planes across the EDOF range. FIG. 11A shows that light rays r1, r2, and r3 each travel different optical path length. FIG. 11B shows that the profile at each incident position A, B, C is the same regardless of the optical path length. For a Gaussian beam, a varying line thickness would be observed along the line as the Gaussian beam diverges with propagation, hence with optical path length.

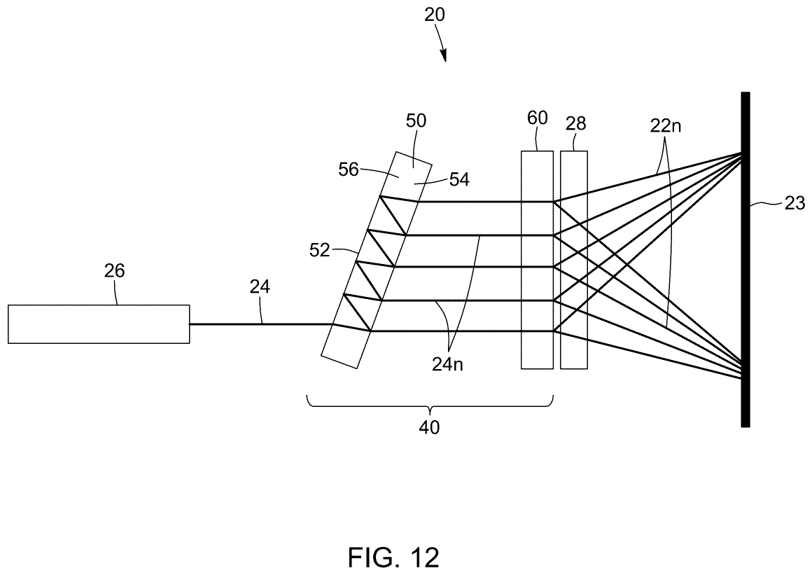

Referring to FIG. 12, there is shown another example of implementations of a light sheet generating assembly 20 for generating a light sheet 22 wherein the line generator 40 is a low-speckle laser line generator according to FIG. 9 of PCT/CA2023/050825. The illustrated light sheet generating assembly 22 includes or is combined with a laser light source 26 generating a light beam 24 having a temporal coherence characterized by a coherence length. The laser light source 26 may for example be embodied by a gas laser, a solid-state laser, a fiber laser, a dye laser or a semiconductor (diode) laser. In some implementations, the laser source is embodied by a laser diode, such as for example a Fabry-Perot (FP) laser diode, a Distributed Feedback (DFB laser diode), a Distributed Bragg Reflector (DBR) laser diode, a Quantum Cascade (QCL) laser diode, Vertical Cavity Surface Emitting Lasers (VCSELs) laser diode, or the like. In some implementations, the configuration of FIG. 12 may be adapted for use with a singlemode laser diode as the laser source 26, although a multimode laser diode may also be used.

Still referring to FIG. 12, the illustrated light sheet generating assembly 30 includes a line generator 40. In this instance, the line generator 40 includes a beam divider 50. The beam divider 50 may for example correspond to any one of the variants illustrated in FIGS. 3A to 3D of PCT/CA2023/050825 or equivalents thereof. For example, the beam divider 50 may include a high reflectivity reflector 52 and a partially reflective reflector 54 extending in parallel and defining a light cavity 56 therebetween. The light cavity 56 has a light input 58 configured to receive the light beam 24 so that it is reflected within the light cavity 56 for multiple passes. Preferably, the light beam has an optical path within each of these passes longer than the coherence length. Each of the passes generates one of multiple incoherent sub-beams 24a, 24b . . . 24n, propagating in a same propagation plane, corresponding to the YZ plane in the referential system of FIG. 12. The line generator 40 of FIG. 12 further includes a sub-beam converter 60 generating a plurality of sub-light sheets 22a, 22b . . . 22n. The sub-beam converter 60 may for example be embodied by a bulk diffraction grating, such as for example a holographic pattern engraved or photoinduced into a planar glass substrate or a plurality of metasurfaces deposited on a surface of a planar glass substrate. Each laser light sheet 22a, 22b . . . 2n extends within the propagation plane YZ. The laser light sheets 22a, 22b . . . 22n intersects at a projection plane to define laser line elements overlapping at least partially to form the low-speckle laser line 23, the laser line elements having respective speckle patterns which are at least partially uncorrelated.

The illustrated light sheet generating assembly 20 of FIG. 12 further includes a depth of field extender 28. It will be noted that in this embodiment, the depth of field extender 28 is positioned downstream the line generator 40. As explained above, the depth of field extender 28 is configured to alter an electrical field of the light beam (in this case after it is transformed into the sub-light sheets 22a, 22b . . . 22n) to redistribute the light intensity of the light beam along the first transverse axis orthogonal to the propagation axis according to an inner intensity peak having a width over the EDOF range which is a constant or scaled to a secondary parameter, and outer intensity features collectively having an intensity below an outer intensity threshold over said EDOF range. In one example, the depth of field extender may be a refractive or diffractive element having an optical surface with a unidimensional profile configured to provide the desired alteration of the electrical field of the light beam.

In other variants, the light sheet generating assembly may have a configuration such as shown on FIGS. 10, 13 and 14 of PCT/CA2023/050825, in which the beam conditional component (element 108) is replaced by a depth of field extender such as described herein.

In some examples of implementations, the depth of field extender 28 may advantageously be independent of the size and wavelength of the input light beam. One skilled in the art will understand that in such implementation, the depth of field improvement when compared to a Gaussian beam is greater as the wavelength shift towards the IR spectrum. This is because the depth of field of a Gaussian beam, for the same waist dimensions, is inversely proportional to the wavelength (i.e it is larger for short wavelength, toward the UV spectrum) while it stays the same through all wavelength for the approach discussed herein.

As will be readily understood by one skilled the art, the light sheet generating assembly described herein may be embodied using a wide variety of optical elements and configurations. In some variants, the depth of field extender and the line generator may be physically separated components, such as illustrated herein, whereas in other implementations they may be bonded or cemented. In some implementations, the light sheet generating assembly may be embodied by a monolithic component for which one of the input or output face act as the depth of field extender and the other one of the input or output surface acts as the line generator. It will also be understood that in alternative variants to the ones shown herein the line generator may be placed ahead of the depth of field extender without departing from the scope of protection.

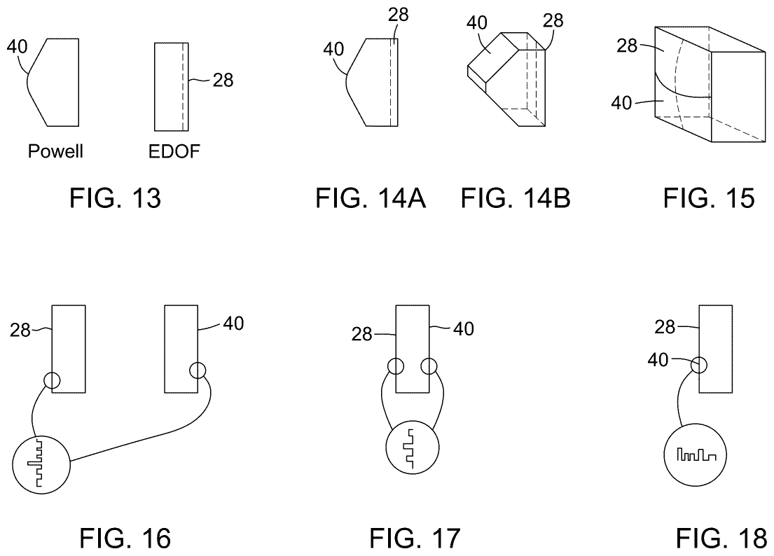

Referring to FIGS. 13 to 15, there are shown different configurations of light sheet generating assemblies using refractive complements, for illustrative purposes only. FIG. 13 shows a configuration in which the depth of filed extender 28 and the line generator 40 are two separate components, with the line generator being positioned ahead of the depth of field extender 28. The depth of field extender 28 is embodied by a refractive component and the line generator 40 by a line-generating lens. FIGS. 14A and 14B shows another configuration wherein a single refractive component embodies both the depth of field extender 28 and the line generator, for example by shaping opposite optical surfaces of the monolithic component to alter the light beam along the first and second transversal axes. Alternatively, referring to FIG. 15, a single optical surface of a monolithic component may be shaped to alter the light beam along both transversal axes, embodying both the depth of field extender 28 and the line generator 40.

Referring to FIGS. 16 to 18, there are shown different configurations of light sheet generating assemblies using diffractive complements, for illustrative purposes only. FIG. 16 shows an example in which to different diffractive component embody the depth of field extender 28 and the line generator 40. FIG. 17 shows a case in which opposite surfaces of a single, monolithic diffractive components embody the depth of field extender 28 and the line generator 40. Finally, FIG. 18 shows a case in which a same surface of a single, monolithic diffractive component embodies both the depth of field extender 28 and the line generator 40. In each case, the diffractive component may be or include a metalens, a multilevel grating, a Fresnel grating, etc.

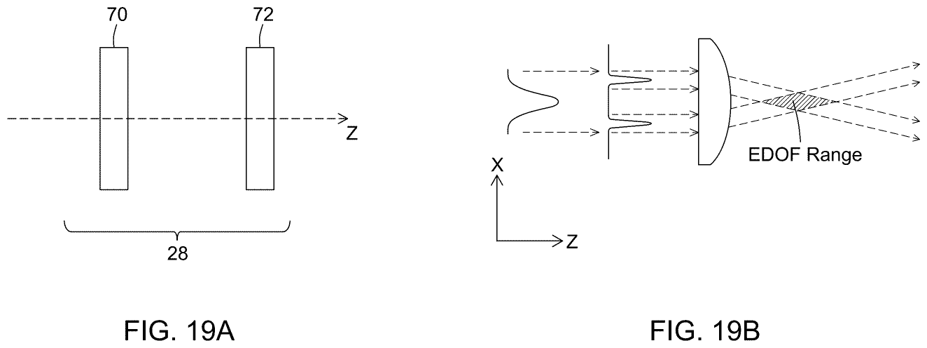

The examples above relate to cases wherein the depth of field extender is configured to alter the phase of the electrical field of the light beam. As mentioned above, in other embodiments the depth of field extender may alternatively or additionally alter the intensity of the electrical field. Referring to FIGS. 19A and 19B, there is shown a variant where the depth of field extender 28 includes an intensity-altering component 70 followed by a phase-altering component 72. In other variants, the order of the intensity-altering and the phase-altering components 70 and 72 may be reversed, and additional components may also be included in the depth of field extender 28. The intensity-altering component 70 may for example be embodied by or include an anodization mask, that is a component designed to alter the intensity profile of a light beam. The phase-altering component 72 may be embodied by a free-form lens, a diffraction grating, or the like. In other variants, the phase-altering component 72 may be omitted such that only the intensity of the light beam is altered by the depth of field extender 28. One skilled in the art will readily understand that variants wherein the intensity of the light beam is altered may inherently suffer from greater transmission losses than phase-only variants.

As will be readily understood by one skilled in the art, all of the embodiments described herein may further be coupled with other optics in order to achieve more complex solutions. As a first example, the depth of field extender may be coupled with a binary grating to obtain an extended depth of field multi line laser. Higher orders generated by the grating may suffer from spectral dispersion to a certain degree, although the effect can be neglected in many cases and still showcases when coupling a binary grating with a Gaussian beam. In a second example, the light sheet generating assembly may be used to generate an EDOF line which acts as the input object to an imaging lens system, such as a 4F relay imaging lens system. The imaging lens system will create an output image for which the dimensions will be scaled according to the imaging lens system properties. By using this technique, the distance on which the outer features stay below the intensity threshold can be notably enhanced for small central lobe (e.g 10 μm or less at FWHM) compared to using solely and extended depth of field lens.

Of course, numerous additional modifications could be made to the embodiments described above without departing from the scope of protection as defined in the appended claims.

1. A light sheet generating assembly for generating a light sheet having an extended depth of field (EDOF) over an EDOF range from a light beam, the light beam having a propagation axis and a light intensity distribution transverse to the propagation axis, the light sheet generating assembly comprising:
a depth of field extender configured to alter an electrical field of the light beam to redistribute the light intensity of the light beam along a first transverse axis orthogonal to the propagation axis according to:
an inner intensity peak; and
outer intensity features having an intensity below an outer intensity threshold over said EDOF range; and
a line generator configured to redistribute the light intensity of the light beam along a second transverse axis orthogonal to the first transverse axis and to the propagation axis into a line.

2. The light sheet generating assembly according to claim 1, wherein the depth of field extender comprises a phase-altering component configured to alter a phase of the electrical field of the light beam and/or an intensity-altering component configured to alter an amplitude of the electrical field of the light beam.

3. The light sheet generating assembly according to claim 1, wherein the depth of field extender comprises an optical surface having a unidimensional surface profile along the first transversal axis providing said redistribution of the light intensity of the light beam along the first transverse axis.

4. The light sheet generating assembly according to claim 3, wherein the unidimensional surface profile is acylindrical.

5. The light sheet generating assembly according to claim 4, wherein the unidimensional surface profile has no inflexion points.

6. The light sheet generating assembly according to claim 1, wherein the inner intensity peak has a constant width over the EDOF range.

7. The light sheet generating assembly according to claim 1, wherein the inner intensity peak has a width over the EDOF range which is scaled to a secondary parameter.

8. The light sheet generating assembly according to claim 7, wherein the secondary parameter is a point spread function dimension of a camera receiving the light sheet thereon.

9. The light sheet generating assembly according to claim 1, wherein the outer intensity threshold is between about 30% and about 50% of a maximum intensity of the inner intensity peak.

10. The light sheet generating assembly according to claim 1, wherein the line generator comprises a refractive optical element.

11. The light sheet generating assembly according to claim 1, wherein the line generator comprises a diffractive optical element.

12. The light sheet generating assembly according to claim 1, wherein the line generator is a low-speckle laser line generator comprising:
a beam divider configured to divide the light beam into incoherent multiple sub-beams propagating in a same propagation plane; and
a sub-beam converter generating a plurality of laser light sheets, each laser light sheet being associated with a corresponding one of the sub-beams, each laser light sheet extending within the propagation plane, the laser light sheets intersecting a projection plane to define laser line elements overlapping at least partially to form said low-speckle laser line, the laser line elements having respective speckle patterns which are at least partially uncorrelated.

13. The light sheet generating assembly according to claim 1, wherein the line generator is configured to redistribute the light intensity of the light beam along the second transverse axis according to a flat uniform profile, a super gaussian profile or a cosine correction profile.

14. The light sheet generating assembly according to claim 1, wherein the line generator is positioned after the depth of field extender.

15. The light sheet generating assembly according to claim 1, wherein the line generator is positioned ahead of the depth of field extender.

16. The light sheet generating assembly according to claim 1, wherein the depth of field extender and the line generator form opposite surfaces of a monolithic optical component.

17. The light sheet generating assembly according to claim 1, in combination with a laser light source generating the light beam.

18. The light sheet generating assembly according to claim 17, wherein the laser light source comprises a laser diode.
